(19) United States
(12) Patent Application Publication
(10) Pub. No.: US 2005/0156217 A1
(43) Pub. Date: Jul. 21, 2005

(54) Semiconductor memory device and method for fabricating the same

(75) Inventors: Yasuhiro Shimada, Kyoto (JP); Daisuke Ueda, Osaka (JP)

Correspondence Address: Jack Q. Lever, Jr.;McDERMOTT, WILL & EMERY LLP, 600 Thirteenth Street, N.W., Washington, DC, 20005-3096, US

(73) Assignee: MATSUSHITA ELECTRIC INDUSTRIAL CO., LTD.

(21) Appl. No.: 11/000,047

(22) Filed: Dec. 1, 2004

(30) Foreign Application Priority Data
Jan. 13, 2004 (JP) 2004-005266
Jan. 15, 2004 (JP) 2004-008504

(51) Int. Cl. G11C 11/22

(52) U.S. Cl. 257/296

(57) ABSTRACT

A semiconductor memory device includes a plurality of memory cells. Each memory cell includes a capacitor which is composed of a first electrode, at least one particle made of ferroelectric or high dielectric constant material and selectively arranged on the first electrode, and a second electrode formed on the particle.

### CROSS REFERENCE TO RELATED APPLICATIONS

This Non-provisional application claims priority under 35 U.S.C. § 119(a) on Patent Application NO. 2004-005266 filed in Japan on Jan. 13, 2004 and Patent Application NO. 2004-008504 filed in Japan on Jan. 15, 2004, the entire contents of which are hereby incorporated by reference.

### BACKGROUND OF THE INVENTION

(a) Fields of the Invention

The present invention relates to semiconductor memory devices for storing data in memory cells using capacitors each with a capacitor insulating film including ferroelectric or high dielectric constant material, AND to methods FOR fabricating such a device.

(b) Description of Related Art

Conventional semiconductor memory devices in which a ferroelectric capacitor and a transistor constitute a memory cell have circuitry exemplarily shown in FIG. 13.

In FIG. 13, a first electrode 1 of a ferroelectric capacitor 10 is connected to a source 4 of a transistor 7, and a second electrode 2 thereof is connected to a cell plate line 9. A drain 5 of the transistor 7 is connected to a bit line 8, and a gate 6 thereof is connected to a word line 11.

As an exemplary device structure of the memory cell, a stacked structure shown in FIG. 14 can be employed (see, for example, Japanese Unexamined Patent publication No. 2003-289134). In this structure, a first electrode 1 of a ferroelectric capacitor 10 is connected to a source 4 of a transistor 7 with a first contact plug 12 interposed therebetween, and a second electrode 2 thereof is connected to a cell plate line 9. A drain 5 of the transistor 7 is connected to a bit line 8 with a second contact plug 13 interposed therebetween, and a gate 6 thereof is connected to a word line (not shown).

In the memory cell of this structure, the ferroelectric capacitor 10 is formed by the following method. As exemplarily shown in FIG. 15A, on a base substrate made by forming a first insulating layer 21 on a silicon substrate 20, the first electrode 1, a ferroelectric film 3, and the second electrode 2 are sequentially stacked, and then a photoresist mask 24 of desired shape is formed on the second electrode 2. Using the mask 24 as an etching mask, the second electrode 2, the ferroelectric film 3, and the first electrode 1 are subjected to plasma etching or the like, thereby forming a capacitor shown in FIG. 15B.

### SUMMARY OF THE INVENTION

However, the conventional semiconductor memory device described above has a problem. An etching gas during the plasma etching contains a large quantity of activated species such as reactive radicals. Therefore, as shown in FIG. 15C, the abundant reactive radicals damage edges of the ferroelectric film 3 inwardly. As a result, damage regions 30 no longer exhibiting any ferroelectric properties are created in the perimeter of the ferroelectric capacitor 10.

The damage regions 30 created in the ferroelectric film 3 reduce the effective area of the ferroelectric capacitor 10. To be more specific, the damage regions 30 extend inwardly from the edges of the ferroelectric capacitor 10 to depths as great as tens to hundreds of nanometers. If the area of the ferroelectric capacitor 10 is less than 1 μm², the decrease in the effective area of the ferroelectric capacitor 10 cannot be ignored in terms of the device characteristics. Moreover, the scope of the damage region 30 is determined by the processing method of the ferroelectric capacitor 10 and does not depend upon the dimension (area) of the ferroelectric capacitor 10 on the semiconductor substrate.

To reduce the above-mentioned creation of the damage regions 30, annealing for restoration of damages is performed after the formation of the ferroelectric capacitor 10. However, this annealing cannot completely eliminate the damage regions 30. Moreover, the damage-restoration annealing is performed at almost the same temperature as the crystallization temperature of the ferroelectric. Therefore, if multiple layers each with a ferroelectric capacitor 10 are stacked, the damage-restoration annealing has to be performed on every layer. This brings about thermal degradation of interconnects between the layers or other troubles. As a result, it becomes difficult to realize a capacitor array in which the ferroelectric capacitors 10 are stacked.

In addition, the conventional fabrication method described above has a problem. Specifically, in the process step shown in FIG. 15A, on the entire surface of the first electrode 1, the ferroelectric film 3 is formed by a spattering method, a sol-gel method, or the like. Therefore, the formed ferroelectric film is inevitably polycrystallized. Although ferroelectrics produce their polarization by making their crystal orientations isotropic, the above polycrystalline ferroelectric film would level out the direction of polarization. Accordingly, it is difficult to control the crystal orientations of the polycrystalline ferroelectric film to those by which the deviation of polarization can be maximized.

An object of the present invention is to solve the conventional problems described above, that is to say, to prevent creation of a damage region in a capacitor insulating film made of ferroelectric or high dielectric constant material, and to maintain, in a capacitor insulating film made of ferroelectric, the deviation of polarization of the ferroelectric at a high degree.

To attain the above object, in the present invention, a capacitor insulating film made of ferroelectric or high dielectric constant material and constituting a capacitor is formed, on a lower electrode (a first electrode), selectively or in a self-aligned manner.

Specifically, a semiconductor memory device of the present invention is characterized by comprising a plurality of memory cells. The device is characterized in that the memory cells each include a capacitor which is composed of a first electrode, at least one particle made of ferroelectric or high dielectric constant material and selectively arranged on the first electrode, and a second electrode formed on the particle.

In the semiconductor memory device of the present invention, as a capacitor film forming the capacitor, the particle is used which is made of ferroelectric or high dielectric constant material and which is selectively arranged on the first electrode. Therefore, unlike the conventional device, the necessity to pattern a ferroelectric film of film shape into a predetermined shape is eliminated. Consequently, the capacitor film of particle shape can prevent creation of damage regions due to etching during the patterning.

Preferably, in the semiconductor memory device of the present invention, the first electrodes of the memory cells are regularly arranged on a semiconductor substrate.

Preferably, the semiconductor memory device of the present invention further comprises an insulating film formed on the first electrodes. The device is characterized in that the insulating film includes a plurality of openings reaching the first electrodes, respectively, and the particles enter in the openings so that a part of the particle of the each memory cell is in contact with the first electrode. With this device, in forming the capacitor film, the region of the semiconductor substrate on which the first electrodes are absent is masked by the insulating film, which further enhances the selectivity of arrangement of the particles on the first electrodes.

Preferably, in the semiconductor memory device of the present invention, the particles are sintered in advance into a crystal phase to exhibit ferroelectricity. This eliminates heat treatment for crystallization of the ferroelectric material forming the particles, thereby preventing thermal degradation of interconnects or the like.

Preferably, in the above case, each said particle is a single crystal or a crystal of mono-domain. This suppresses the phenomenon in which polycrystallization disperses the direction of occurrence of polarization of the particle resulting from the imparted isotropy of crystal orientations. Therefore, the crystal orientation of each particle made of ferroelectric or high dielectric constant material can be easily oriented in the direction in which the deviation of polarization of the particle is maximized.

Preferably, in the semiconductor memory device of the present invention, the standard deviation representing the variation in the particle diameter is equal to or smaller than the average value of the particle diameters. This improves the selectivity of each particle made of ferroelectric or high dielectric constant material to the arrangement position and improves the homogeneity of electric characteristics of the capacitors.

Preferably, in the semiconductor memory device of the present invention, the capacitors are connected to respective select switches to form a memory cell array. With this structure, if the select switch is a transistor, the memory cell array can be operated in an active matrix method and any cell in the memory cell array can be selected from the outside of the array.

Preferably, in the above case, the select switch is formed of a transistor, a bidirectional diode or a unidirectinal diode. With this structure, if the select switch is a transistor, the memory cell array can be operated in an active matrix method. If the select switch is a bidirectional diode or a unidirectinal diode, the memory cell array can be operated in a simple matrix method.

Preferably, the semiconductor memory device of the present invention comprises: a first memory cell array in which the multiple memory cells are arranged; and a second memory cell array formed on the first memory cell array and having the same structure as the first memory cell array. Such a three-dimensional arrangement of the memory cell arrays can increase the cell density in the memory cell array of the semiconductor memory device.

A first method for fabricating a semiconductor memory device according to the present invention is characterized by comprising the step of: (a) selectively forming a plurality of first electrodes on a semiconductor substrate; (b) dispersing in a liquid a plurality of particles made of ferroelectric or high dielectric constant material; (c) selectively arranging the particles on the plurality of first electrodes, respectively, while the semiconductor substrate with the first electrodes formed thereon is immersed in the liquid; and (d) forming a second electrode on the particles to form a plurality of capacitors each of which is composed of at least one of the first electrodes, at least one of the particles, and the second electrode.

With the first method for fabricating a semiconductor memory device, unlike the conventional device, the necessity to pattern a ferroelectric film of film shape into predetermined shape is eliminated. Consequently, the capacitor film of particle shape can prevent creation of damage regions due to etching during the patterning. Moreover, the plurality of particles are dispersed in the liquid in the step (b), which facilitates supply of the particles onto the semiconductor substrate, that is, onto the first electrodes. Furthermore, the ferroelectric in the present invention can be prevented from the phenomenon in which polycrystallization randomly disturbs the direction of occurrence of polarization resulting from the imparted isotropy of crystal orientations, so that the crystal orientation of the ferroelectric can be controlled in the direction in which the deviation of polarization thereof is maximized. Therefore, the data writing and reading characteristics of the memory cell are significantly improved.

Preferably, in the first method for fabricating a semiconductor memory device, in the step (b), the particles are monodispersed in a liquid. This prevents the multiple particles from being arranged on each of the first electrodes.

Preferably, in the first method for fabricating a semiconductor memory device, before the step (b), the particles are sintered into a crystal phase to exhibit ferroelectricity. This eliminates heat treatment for crystallization of the ferroelectric material forming the particles, thereby preventing thermal degradation of interconnects or the like.

Preferably, in the above case, each said particle is a single crystal or a crystal of mono-domain. This suppresses the phenomenon in which polycrystallization disperses the direction of occurrence of the polarization of the particle resulting from the imparted isotropy of crystal orientations. Therefore, the crystal orientation of each particle made of ferroelectric or high dielectric constant material can be easily oriented in the direction in which the deviation of polarization of the particle is maximized.

Preferably, in the first method for fabricating a semiconductor memory device, in the step (c), an electric field is applied to the particles. This enhances the selectivity of arrangement of each particle made of ferroelectric or high dielectric constant material.

Preferably, in the first method for fabricating a semiconductor memory device, in the step (c), mechanical vibration is applied to the particles or the semiconductor substrate. This enhances the selectivity of arrangement of each particle made of ferroelectric or high dielectric constant material.

Preferably, in the first method for fabricating a semiconductor memory device, in the step (c), the particles are radiated with energy beams. This increases translational kinetic energies of the particles made of ferroelectric or high dielectric constant material, thereby activating the particles. Therefore, the selectivity of arrangement of each particle is enhanced.

Preferably, the first method for fabricating a semiconductor memory device further comprises, between the steps (c) and (d), the step (e) of forming an insulating film on the semiconductor substrate so that the particles are covered with the insulating film, and the step (f) of removing an upper portion of the insulating film until a part of the particles are exposed. This prevents a short circuit between the first and second electrodes and ensures an electrical contact between the second electrode and each particle.

A second method for fabricating a semiconductor memory device according to the present invention is characterized by comprising the step of: (a) forming a first electrode on a semiconductor substrate; (b) forming a thin film on the first electrode; (c) forming in the thin film an opening reaching the first electrode; (d) selectively forming a capacitor insulating film of ferroelectric or high dielectric constant material in the opening formed in the thin film or in the opening and on its vicinity; and (e) forming a second electrode on the capacitor insulating film to form a capacitor composed of the first electrode, the capacitor insulating film and the second electrode.

The second method for fabricating a semiconductor memory device, unlike the conventional device, the necessity to pattern a ferroelectric film of film shape into predetermined shape is eliminated. Consequently, the capacitor insulating film thus formed can prevent creation of damage regions due to etching during the patterning.

Preferably, in the second method for fabricating a semiconductor memory device, in the step (d), the capacitor insulating film is formed by a metal organic chemical vapor deposition method in which a source gas for the ferroelectric or high dielectric constant material is formed into ion clusters. With this method, no ion-clustered source gas is made cohesive and thermally decomposed on any portions other than the openings and their vicinity. Therefore, the ferroelectric is grown into a single crystal only on the portions of the first electrode exposed in the openings formed in the thin film, which ensures a high growth selectivity.

Preferably, in the second method for fabricating a semiconductor memory device, in the step (d), the capacitor insulating film is formed by an electrophoresis method using ferroelectrics or high dielectric constant materials monodispersed in a liquid. With this method, the ferroelectrics or dielectrics of high dielectric constant are dispersed in the liquid, which facilitates a selective supply of the ferroelectric onto the first electrode.

Preferably, in the above case, in the step (d), mechanical vibration is applied to the semiconductor substrate.

Preferably, in the above case, in the step (d), the monodispersed ferroelectrics or high dielectric constant materials are radiated with energy beams.

Preferably, in the second method for fabricating a semiconductor memory device, in the step (c), the opening is formed by radiating energy beams directly on a portion of the thin film to alter the portion and removing the altered portion.

Preferably, in the second method for fabricating a semiconductor memory device, the thin film is an insulating film. This prevents a short circuit between the first and second electrodes.

### BRIEF DESCRIPTION OF THE DRAWINGS

FIG. 1 is a sectional view showing the structure of principle parts of a semiconductor memory device according to a first embodiment of the present invention.

FIG. 2 is a sectional view schematically showing a process step of a ferroelectric capacitor fabrication method in the semiconductor memory device according to the first embodiment of the present invention.

FIG. 3 is a sectional view schematically showing a liquid treatment step of the ferroelectric capacitor fabrication method in the semiconductor memory device according to the first embodiment of the present invention.

FIG. 4 is a sectional view schematically showing a process step of the ferroelectric capacitor fabrication method in the semiconductor memory device according to the first embodiment of the present invention.

FIG. 5 is a graph showing the polarization hysteresis characteristics of the ferroelectric capacitor of the semiconductor memory device according to the first embodiment of the present invention.

FIGS. 6A to 6F are sectional views schematically showing, step by step, process steps of a ferroelectric capacitor fabrication method in a semiconductor memory device according to a modification of the first embodiment of the present invention.

FIG. 7 is a sectional view showing the structure of principle parts of a semiconductor memory device according to a second embodiment of the present invention.

FIGS. 8A to 8C are sectional views schematically showing, step by step, process steps of a ferroelectric capacitor fabrication method in a semiconductor memory device according to a third embodiment of the present invention.

FIGS. 9A and 9B are sectional views schematically showing, step by step, process steps of the ferroelectric capacitor fabrication method in the semiconductor memory device according to the third embodiment of the present invention.

FIGS. 10A to 10C are sectional views schematically showing, step by step, process steps of the ferroelectric capacitor fabrication method in the semiconductor memory device according to the third embodiment of the present invention.

FIG. 11 is a graph showing the polarization hysteresis characteristics of the ferroelectric capacitor of the semiconductor memory device according to the third embodiment of the present invention.

FIG. 12 is a sectional view schematically showing a liquid treatment step of a ferroelectric capacitor fabrication method in a semiconductor memory device according to a modification of the third embodiment of the present invention.

FIG. 13 is an equivalent circuit diagram showing a conventional ferroelectric memory cell array.

FIG. 14 is a sectional view showing the structure of principle parts of a conventional semiconductor memory device.

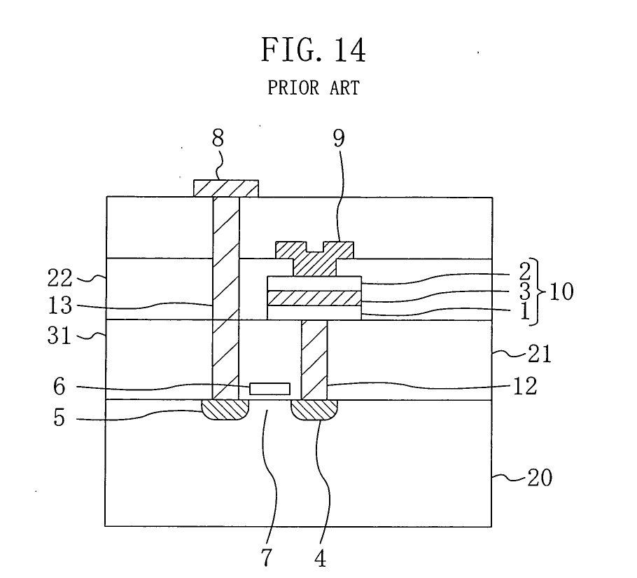

FIG. 15 is sectional views showing process steps of a ferroelectric capacitor fabrication method in the conventional semiconductor memory device step by step.

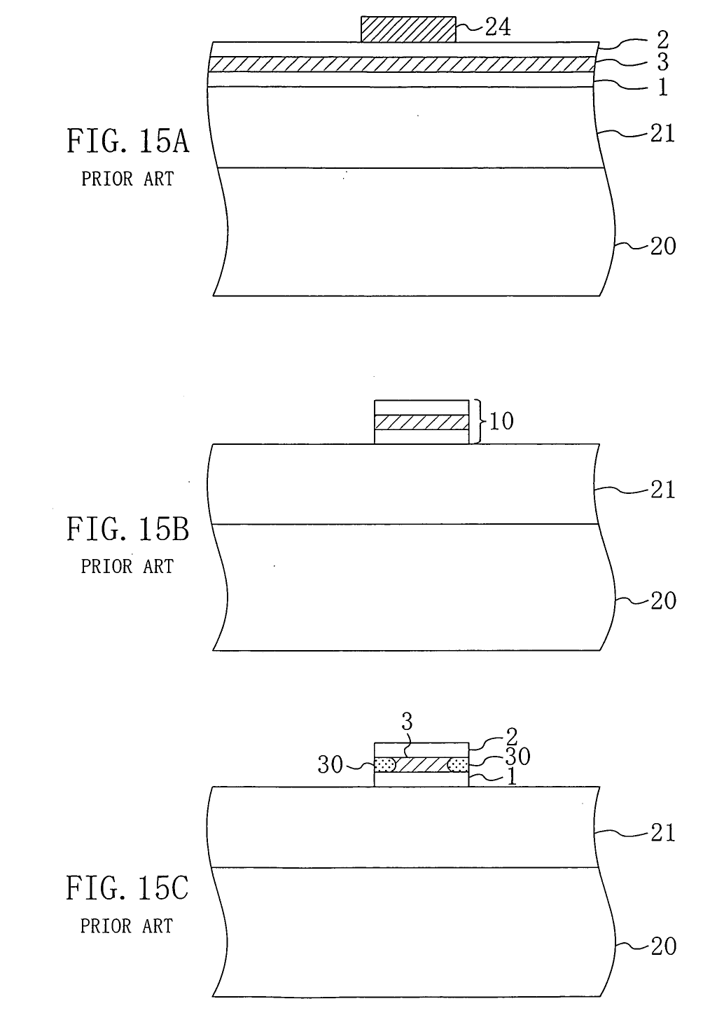

### DETAILED DESCRIPTION OF THE PREFERRED EMBODIMENTS

### First Embodiment

A first embodiment of the present invention will be described with reference to the accompanying drawings.

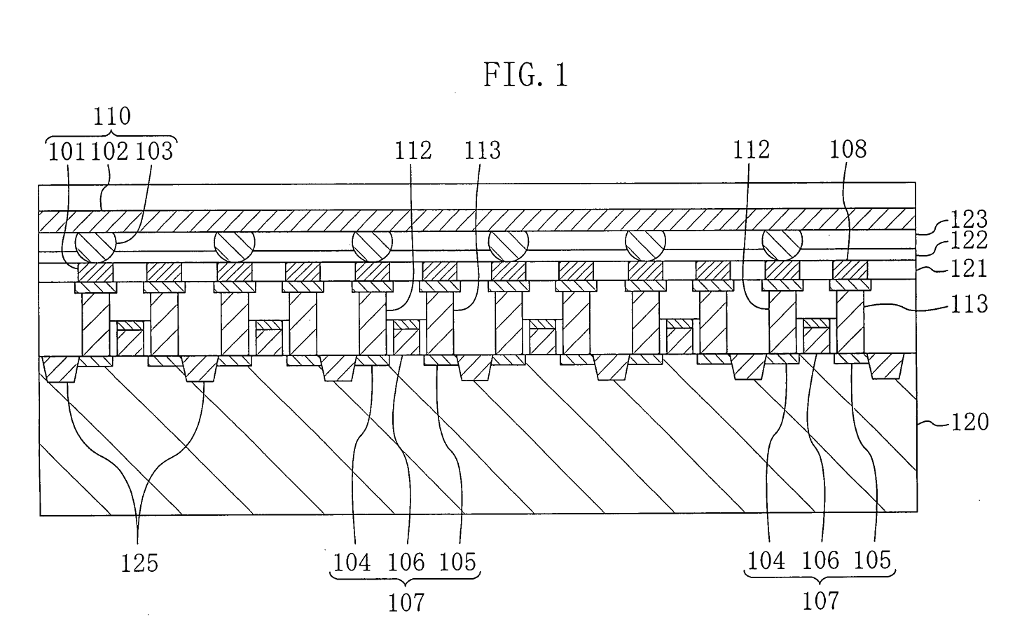

FIG. 1 shows a semiconductor memory device according to the first embodiment of the present invention, and shows the cross-sectional structure of principle parts of the semiconductor memory device in which a plurality of ferroelectric capacitors are arranged in array form above a semiconductor substrate.

Referring to FIG. 1, on the main surface of a semiconductor substrate 120 made of, for example, silicon (Si), a plurality of ferroelectric capacitors 110 are formed in array form. Between the ferroelectric capacitors 110, a plurality of transistors 107 are interposed, respectively, which serve as select switches.

Isolation films 125 made of, for example, shallow trench isolation (STI) are selectively formed in an upper portion of the semiconductor substrate 120. Each of the transistors 107 is formed in an element region defined by the isolation films 125, and composed of a doped source layer 104, a doped drain layer 105, and a gate electrode 106 formed between these doped layers 104 and 105. Note that the select switch is not limited to the transistor 107, and a bidirectional diode or a unidirectinal diode may be used instead.

Each of the ferroelectric capacitors 110 is composed of a first electrode 101, a particle 103 serving as a capacitor film, and a second electrode 102. The first electrode 101 is made of, for example, platinum (Pt). The particle 103 is formed on the first electrode 101 and made of ferroelectric or high dielectric constant material. The second electrode 102 of platinum (Pt) is formed to spread over the multiple particles 103 and also serves as a cell plate line. The diameter of the particle 103 is preferably about 5 to 500 nm. A plurality of particles 103 may be formed on each of the first electrode 101.

The circumferences of the first electrodes 101 are buried in a first insulating film 121 made of, for example, silicon oxide. Each of the particles 103 or an assembly of the particles 103 is buried in a second insulating film 122 and a third insulating film 123 made of, for example, silicon oxide. Note that the second insulating film 122 and the third insulating film 123 are not necessarily formed independently.

The first electrode 101 of each of the ferroelectric capacitors 110 is connected to the doped source layer 104 of the transistor 107 with a first contact plug 112 interposed therebetween. The doped drain layer 105 of the transistor 107 is connected to a bit line 108 with a second contact plug 113 interposed therebetween. The ferroelectric capacitor 110 and the transistor 107 constitute a single memory cell.

In the first embodiment, when the particle 103 or the particle assembly made of ferroelectric or high dielectric constant material is selectively arranged on the first electrode 101, the particle 103 or each particle of the assembly has previously been formed into a single crystal. In this structure, as the ferroelectric, use may be made of, for example, barium titanate (BaTiO₃), lead titanate (PbTiO₃), lead zirconate titanate (Pb(Zr, Ti)O₃), barium strontium titanate ((Sr, Ba)TiO₃), or bismuth lanthanum titanate ((Bi, La)₄Ti₃O₁₂). As the high dielectric constant material, use may be made of, for example, barium strontium titanate ((Sr, Ba)TiO₃), or tantalum pentoxide (Ta₂O₅).

Hereinafter, based on the accompanying drawings, description will be made of an exemplary method for selectively arranging the particle 103 in the semiconductor memory device constructed above. In this device, the particle 103 is made of ferroelectric or high dielectric constant material and serves as a capacitor film.

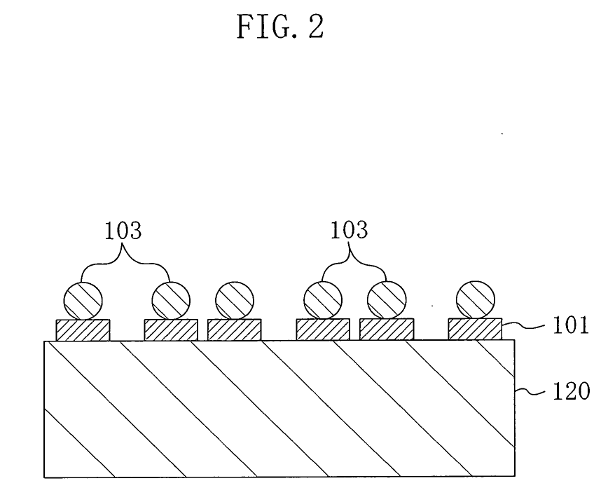

Referring to a schematic view in FIG. 2, the multiple first electrodes 101 are selectively formed on the semiconductor substrate 120 formed with an integrated circuit including the multiple transistors 107 shown in, for example, FIG. 1. In this structure, each of the first electrodes 101 is electrically connected, with a first plug (not shown) interposed therebetween, to a source region of the corresponding transistor formed on the semiconductor substrate 120.

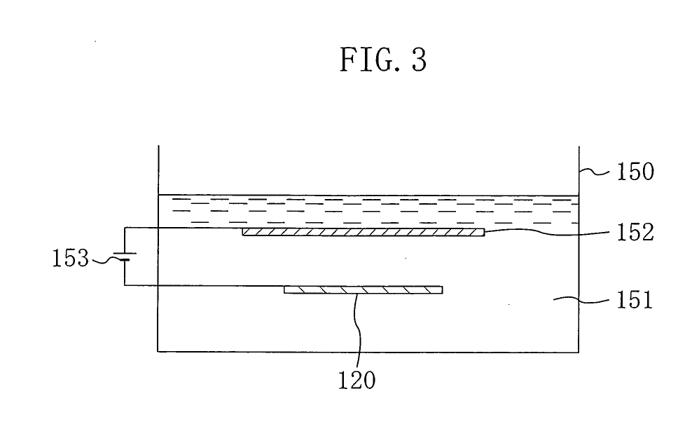

Next, as shown in FIG. 3, the semiconductor substrate 120 is immersed in a liquid treatment bath 150 filled with a liquid 151 containing a number of particles 103 made of, for example, ferroelectric or high dielectric constant material. The liquid 151 has an acidity adjusted to monodisperse the particles 103 of ferroelectric or high dielectric constant material. The particles 103 dispersed in the liquid 151 have previously been sintered, before they are dispersed into the liquid 151, to the crystal phase in which they exhibit ferroelectricity.

Therefore, the particles 103 monodispersed in the liquid 151 have dielectric constants exhibiting a large anisotropy because the particles are single crystals. In such a state, as shown in FIG. 3, the first electrode 101 of the semiconductor substrate 120 is connected to the cathode of a direct current source 153 and a treatment bath electrode 152 immersed in the liquid 151 is connected to the anode of the direct current source 153. Then, a strong electric field is applied between the first electrode 101 and the treatment bath electrode 152. By the resulting interaction between the electric field applied by the treatment bath electrode 152 and a dipole moment of each particle 103 made of ferroelectric or high dielectric constant material, the particles 103 are selectively attracted to the first electrodes 101, respectively. Moreover, the dipole moments of the particles 103 are maximized in the crystal axis direction in which spontaneous polarization arises in the particles, so that the particles 103 are selectively coordinated so that the direction in which their spontaneous polarizations are maximized is naturally in parallel with the applied electric field, that is to say, the particles 103 are selectively coordinated in the perpendicular direction to the surface of the first electrode 101.

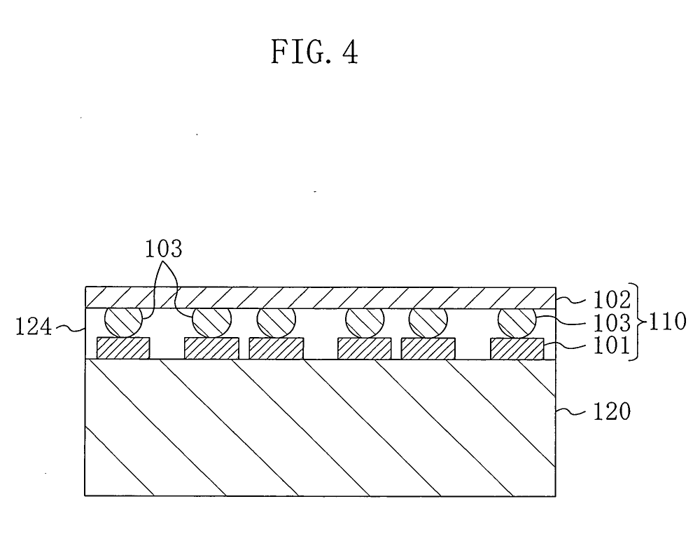

Next, as shown in FIG. 4, on the particles 103 made of ferroelectric or high dielectric constant material and selectively arranged on the first electrodes 101, an insulating film 124 of silicon oxide is deposited by a chemical vapor deposition (CVD) method, a spin on glass method, or the like. Subsequently, by an etch back method or a chemical mechanical polishing method, the surface of the deposited insulating film 124 is planarized until the particles 103 are uniformly exposed. On the planarized insulating film 124, the second electrode 102 is formed along the direction in which the exposed particles 103 are contained and which intersects the first electrodes 101. Thus, at the respective intersections of the first electrodes 101 and the second electrode 102, the ferroelectric capacitors 110 are formed each of which is composed of the first electrode 101, the particle 103, and the second electrode 102.

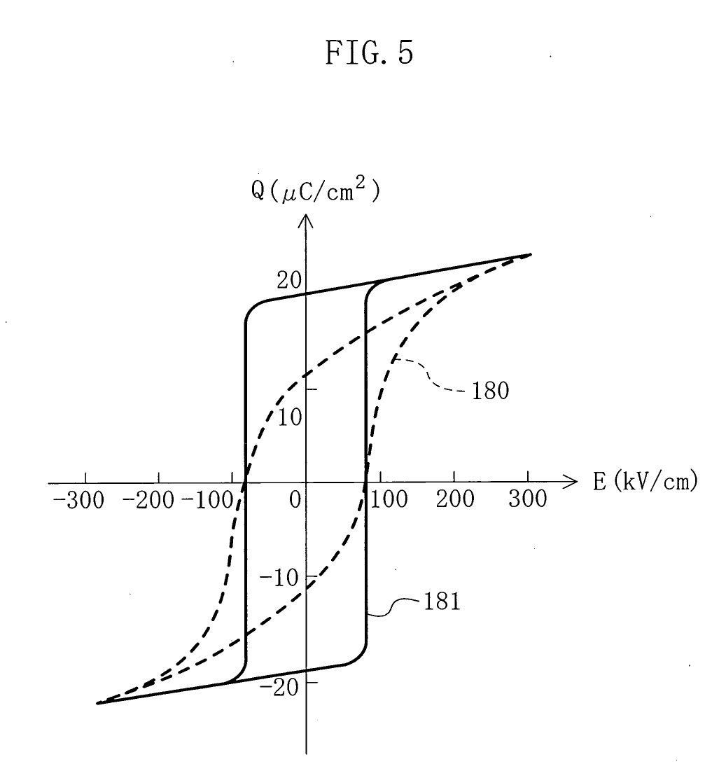

As shown above, in the ferroelectric capacitor 110 of the first embodiment, the particle 103 made of ferroelectric or high dielectric constant material and forming the capacitor film is made of a single crystal, and an electric field is applied in the direction in which the crystal orientation thereof exhibits a large polarization. Therefore, as shown in FIG. 5, the polarization hysteresis characteristics 181 of the ferroelectric capacitor 110 have an outstanding electric field response as compared to the polarization hysteresis characteristics 180 of the conventional ferroelectric capacitor made of polycrystal. Thus, when particles of uniform shape are used as the particles 103 of ferroelectric or high dielectric constant material forming the ferroelectric capacitors 110, the patterning step for forming the ferroelectric capacitor 110 becomes unnecessary, which eliminates creation of damage regions by the patterning. Accordingly, the particles 103 can exhibit a large polarization, which significantly improves the data writing and reading characteristics of the memory cell. Note that FIG. 5 plots the strength of the electric field in abscissa and the charge amount per unit area in ordinate.

The particle 103 of ferroelectric or high dielectric constant material may be formed of a domain which has a uniformly aligned crystal orientation or a sole domain.

Moreover, if the standard deviation representing the extend to which the particle diameters of the particles 103 vary is equal to or smaller than the average of the particle diameters, the selectivity of arrangement of the particles 103 and the homogeneity of electric characteristics of the ferroelectric capacitors 110 are significantly improved.

### Modification of First Embodiment

A modification of the first embodiment of the present invention will be described below with reference to the accompanying drawings.

This modification is another example of the method for selectively arranging the particle 103 shown in FIG. 2 according to the first embodiment.

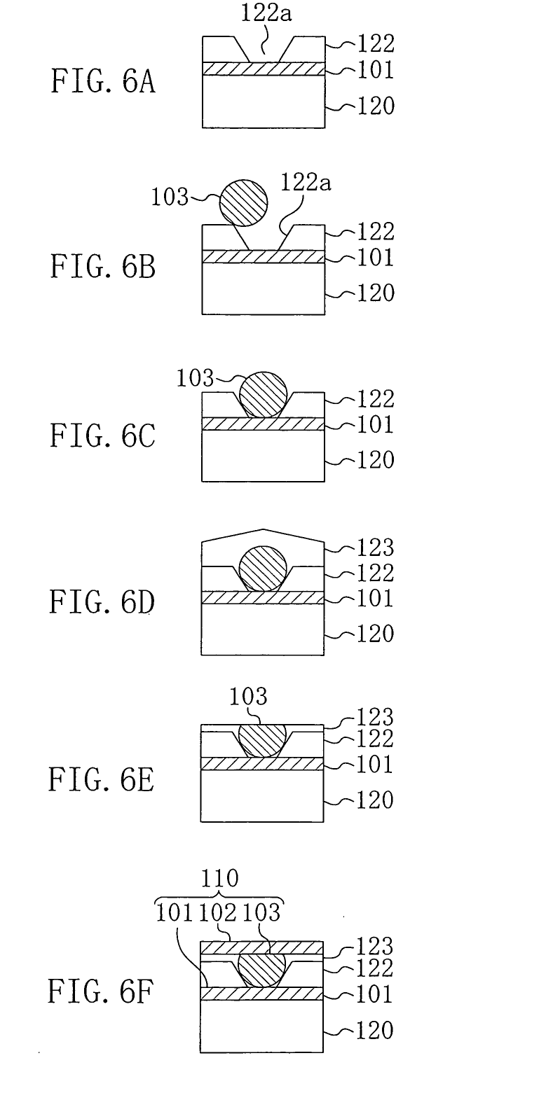

First, on a semiconductor substrate 120 formed with an integrated circuit including multiple transistors 107 shown in, for example, FIG. 1, a first electrode 101 is formed to be electrically connected to a first plug 112. Then, as shown in FIG. 6A, by a CVD method, a second insulating film 122 is grown to cover the first electrode 101 on the semiconductor substrate 120. Note that FIG. 6 shows only one ferroelectric capacitor formation region. Subsequently, through a portion of the second insulating film 122 located on the first electrode 101, an opening 122a with an opening diameter slightly greater than the desired diameter of the particle 103 made of ferroelectric or high dielectric constant material is formed to expose the first electrode 101 therein.

Next, as shown in FIG. 6B, the semiconductor substrate 120 having the second insulating film 122 with the opening 122a formed is immersed in a liquid 151 as shown in FIG. 3 whose acidity has been adjusted to monodisperse a number of particles 103 made of ferroelectric or high dielectric constant material. The particles 103 dispersed in the liquid 151 have previously been sintered, before they are dispersed into the liquid 151, to the crystal phase in which they exhibit ferroelectricity. Since, as mentioned above, the particles 103 made of ferroelectric or high dielectric constant material and monodispersed in the liquid 151 are single crystals, the particles have dielectric constants exhibiting a large anisotropy. On the other hand, the flatness of the semiconductor substrate 120 is varied by the opening 122a provided in the second insulating film 122 on the surface of the substrate, so that a van der Waals potential in the vicinity of the opening 122a varies more greatly than that in the peripheral region of the opening 122a. By the interaction between this van der Waals potential and a dipole moment of the particle 103, as shown in FIG. 6C, the particle 103 is selectively attracted to the first electrode 101. Moreover, the dipole moment of the particle 103 made of ferroelectric or high dielectric constant material is maximized in the crystal axis direction in which spontaneous polarization arises in the particle, so that the particle 103 is selectively coordinated so that the direction in which its spontaneous polarization is maximized is naturally perpendicular to the surface of the first electrode 101.

Next, as shown in FIG. 6D, on the second insulating film 122 and the particle 103, a third insulating film 123 of silicon oxide is deposited by a CVD method, a spin on glass method, or the like.

Then, as shown in FIG. 6E, by an etch back method or a chemical mechanical polishing method, the surface of the deposited third insulating film 123 is planarized until the particle 103 is exposed.

Subsequently, as shown in FIG. 6F, on the planarized third insulating film 123, a second electrode 102 is formed along the direction in which the exposed particle 103 is contained and which intersects the first electrode 101. Thus, at the intersection of the first electrode 101 and the second electrode 102, a ferroelectric capacitor 110 is formed which is composed of the first electrode 101, the particle 103, and the second electrode 102.

As shown above, also in this modification, the particle 103 made of ferroelectric or high dielectric constant material and forming the ferroelectric capacitor 110 is made of a single crystal, and an electric field is applied in the direction in which the crystal orientation thereof exhibits a large polarization. Therefore, as shown in FIG. 5, the polarization hysteresis characteristics 181 of the ferroelectric capacitor 110 have an outstanding electric field response as compared to the polarization hysteresis characteristics 180 of the conventional ferroelectric capacitor made of polycrystal. Thus, when particles of uniform shape are used as the particles 103 of ferroelectric or high dielectric constant material forming the ferroelectric capacitor 110, the patterning step for forming the ferroelectric capacitor 110 can become unnecessary, which eliminates creation of damage regions by the patterning. Accordingly, the particles 103 can exhibit a large polarization, which significantly improves the data writing and reading characteristics of the memory cell.

In the steps, shown in FIGS. 6B and 6C, of selectively arranging on the first electrode 101 the particle 103 made of ferroelectric or high dielectric constant material, mechanical vibration such as ultrasonic wave is applied to the semiconductor substrate 120 immersed in the liquid 151. Then, translational kinetic energy of the particle 103 on the surface of the semiconductor substrate 120, that is, on the surface of the second insulating film 122 increases, whereby the selectivity of the particle 103 to the arrangement position (opening 122a) is enhanced.

Also, in the steps shown in FIGS. 6B and 6C, the particle 103 is radiated with an energy beam such as a light beam or an electron beam to raise translational kinetic energy of the particle 103 on the surface of the second insulating film 122, whereby the selectivity of the particle 103 to the opening 122a can be enhanced.

Moreover, in the steps shown in FIGS. 6B and 6C, if the standard deviation representing the extend to which the particle diameters of a number of particles 103 made of ferroelectric or high dielectric constant material vary is equal to or smaller than the average of the particle diameters, the selectivity of arrangement of the particles 103 and the homogeneity of electric characteristics of the ferroelectric capacitors 110 are significantly improved.

### Second Embodiment

A second embodiment of the present invention will be described with reference to the accompanying drawings.

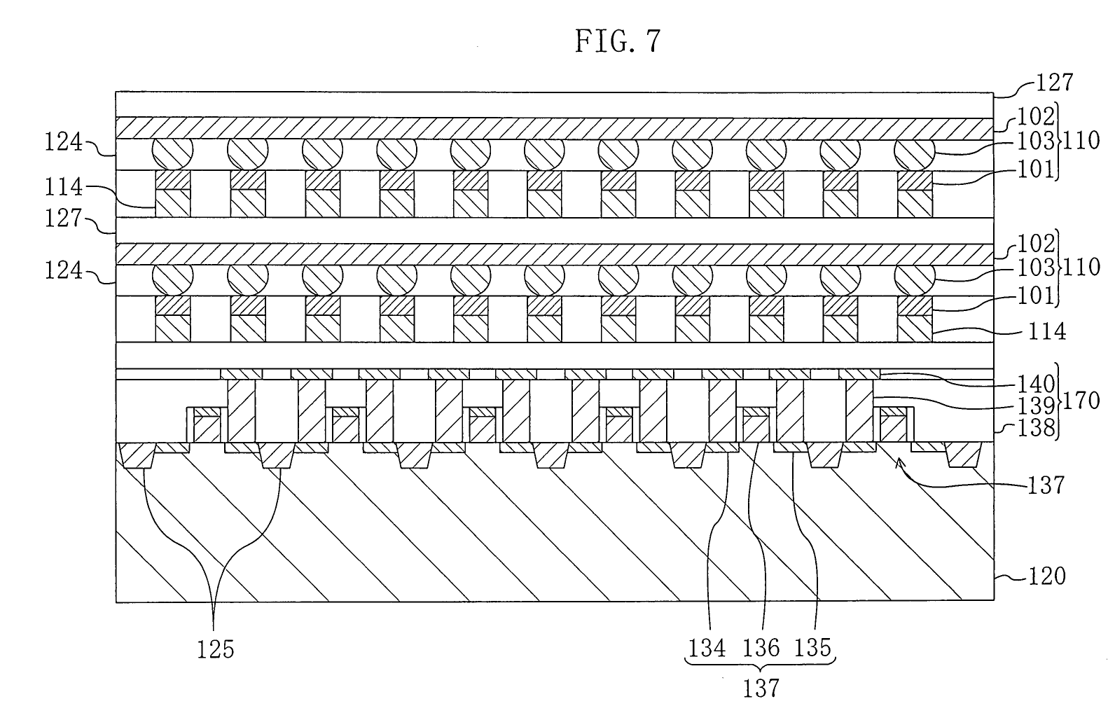

FIG. 7 shows a semiconductor memory device according to the second embodiment of the present invention, and shows the cross-sectional structure of principle parts of the semiconductor memory device in which a plurality of ferroelectric capacitors are arranged, above a semiconductor substrate, in array form with multiple layers. In this embodiment, the structure of the semiconductor memory device and a fabrication method thereof will both be described.

Referring to FIG. 7, first, on the main surface of a semiconductor substrate 120 made of silicon, a peripheral circuit portion 170 is formed which includes a plurality of transistors 137. The transistors 137 are obtained by the following procedure. Isolation films 125 such as STI are selectively formed in an upper portion of the semiconductor substrate 120 to provide a plurality of element regions, and then the element regions are formed with gate electrodes 136, respectively. Using the formed gate electrodes 136 as a mask, dopant ions are implanted into the element regions to form doped source layers 134 and doped drain layers 135 on the sides of the regions of the gate electrodes 136, thereby obtaining the transistors 137. Thereafter, the transistors 137 are buried by a first interlayer insulating film 138 and the first interlayer insulating film 138 is formed with plugs 139 for bringing the doped source layers 134 and the doped drain layers 135 of the respective transistors 137 into electrical conduction. Interconnects 140 are then formed on the plugs 139, respectively.

Subsequently, by a spattering method or a CVD method, a semiconductor thin film 144 of silicon having the n-type conductivity is stacked above the peripheral circuit portion 170, and a first electrode 101 made of platinum (Pt) is stacked on the semiconductor thin film 114. The stacked semiconductor thin film 114 and first electrode 101 are patterned into desired shape, thereby forming a metal-semiconductor Schottky barrier diode.

Similarly to the method described in the first embodiment or its modification, a number of particles 103 made of ferroelectric or high dielectric constant material and having been sintered to exhibit ferroelectricity are in advance monodispersed in a liquid. While the semiconductor substrate 120 is immersed in the liquid with the particles 103 dispersed therein, an electric field is applied to selectively arrange the dispersed particles 103 on the first electrodes 101, respectively.

An insulating film 124 is then deposited on the particles 103 each of which is selectively arranged on the first electrode 101. Subsequently, by an etch back method or a chemical mechanical polishing method, the surface of the deposited insulating film 124 is planarized until the particles 103 are uniformly exposed. On the planarized insulating film 124, a second electrode 102 is formed along the direction in which the exposed particles 103 are contained and which intersects the first electrode 101. Thus, ferroelectric capacitors 110 are formed at the respective intersections of the first electrodes 101 and the second electrode 102. On the second electrode 102, a second interlayer insulating film 127 is formed to obtain a first-layer capacitor subarray.

Next, on the second interlayer insulating film 127, a second-layer capacitor subarray is formed by the same method as the first-layer capacitor subarray formation method. In this manner, a three-dimensionally arranged capacitor array can be formed. Three- and subsequent-layer subarrays are repeatedly formed similarly to the second-layer subarray, whereby a semiconductor memory device can be attained which includes a ferroelectric capacitor array with a desired number of layers and the density of the arranged memory cells can be greatly increased.

Moreover, even for such a three-dimensionally arranged capacitor array, only if the particles of uniform shape are employed as the particles 103 of ferroelectric or high dielectric constant material constituting the ferroelectric capacitors 110, the patterning step for forming the ferroelectric capacitors 110 can become unnecessary. This eliminates creation of damage regions by the patterning. Accordingly, the particles 103 can exhibit large polarizations, which significantly improves the data writing and reading characteristics of the memory cell.

### Third Embodiment

A third embodiment of the present invention will be described with reference to the accompanying drawings.

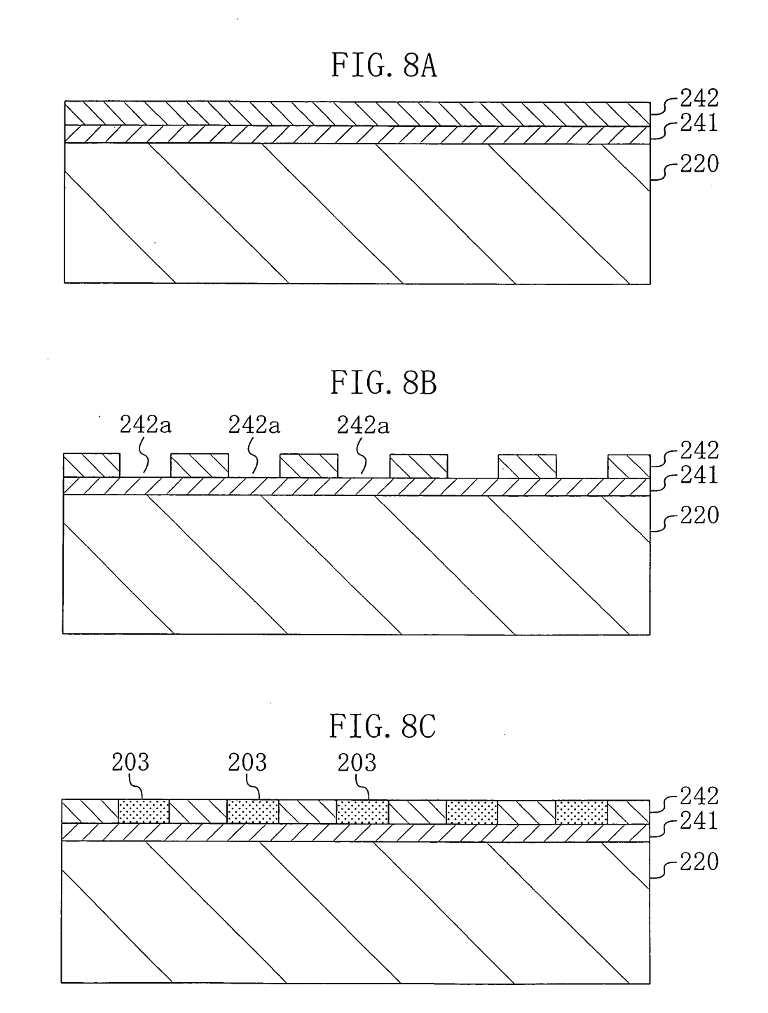

FIGS. 8A to 8C, 9A, 9B, and 10A to 10C show a method for fabricating a semiconductor memory device according to the third embodiment of the present invention, and show the cross-sectional structure thereof step by step when a plurality of ferroelectric capacitors are formed above a substrate.

First, referring to FIG. 8A, on the main surface of a semiconductor substrate 220 made of, for example, silicon (Si), a first electrode 241 made of platinum (Pt) is formed by a spattering method. On the first electrode 241, a thin film 242 made of, for example, silicon dioxide (SiO₂) is then formed by a CVD method.

Subsequently, as shown in FIG. 8B, the formed thin film 242 is formed with a plurality of openings 242a exposing the first electrode 241. It is recommended that the openings 242a have an opening dimension larger than the smallest processable dimension available to a device fabrication process. The openings 242a may be formed so that the thin film 242 is etched using, for a transferring pattern, a photoresist mask (not shown) made by a lithography method, or so that portions of the thin film 242 in which the openings 242a will be formed are directly radiated with energy beams such as an electron beam or an ultraviolet beam to alter those portions and then the altered portions are removed with an aqueous solution of hydrogen fluoride.

Next, as shown in FIG. 8C, capacitor films formed of ferroelectrics 203 are selectively produced in the openings 242a of the thin film 242. If the ferroelectrics 203 are grown to be single crystals, the crystal lattices of the first electrode 241 and the ferroelectric 203 desirably match each other.

For the ferroelectric 203 constituting the capacitor film, use can be made of barium titanate (BaTiO₃), lead titanate (PbTiO₃), lead zirconate titanate (Pb(Zr, Ti)O₃), barium strontium titanate ((Sr, Ba)TiO₃), bismuth lanthanum titanate ((Bi, La)₄Ti₃O₁₂), or the like.

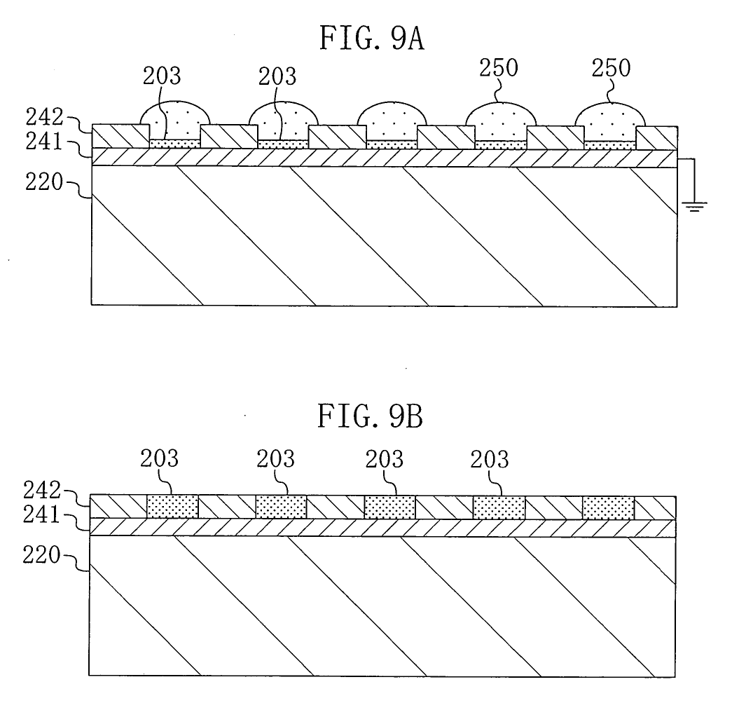

Hereinafter, as an exemplary method for selectively growing the capacitor film formed of the ferroelectric 203, a method for forming into ion clusters a source gas for the ferroelectric 203 constituting the capacitor film is shown in FIGS. 9A and 9B.

Referring to FIG. 9A, for example, the semiconductor substrate 220 with the first electrode 241 electrically grounded is put on a heating unit (not shown) in a reaction chamber containing a source gas 250. As the source gas 250, use is made of a source gas employed for a metal organic chemical vapor deposition (MOCVD) method or the like, and the source gas 250 in the state of being gasified as organometallic molecules is supplied to the reaction chamber. In the third embodiment, the source gas 250 is passed through an ionization unit such as corona discharge path (not shown) before it is supplied to the reaction chamber. Thus, the source gas 250 is ionized into charged ion clusters. In this condition, when the potential of the space within the reaction chamber is set to have an electrostatic potential gradient relative to the semiconductor substrate 220 with the first electrode 241 electrically grounded, the ion-clustered source gas 250 is collected within the openings 242a formed in the thin film 242. Moreover, when the temperature of the semiconductor substrate 220 is set at about the thermal decomposition temperature of the source gas 250, the ion-clustered source gas 250 is thermally decomposed on the first electrode 241, thereby starting selective growth of the ferroelectric 203 on the bottom surfaces of the openings 242a of the thin film 242. FIG. 9A shows the state in which the ion-clustered source gas 250 is thermally decomposed within the openings 242a of the thin film 242 to start selective growth of the ferroelectric 203.

In the step shown in FIG. 9A, the process of cohesion of the ion-clustered source gas 250 on the portions of the first electrodes 241 exposed in the openings 242a of the thin film 242 includes the case where the gas is self organized, that is to say, the gas is self-aligned to become cohesive by the chemical affinity between the molecules or clusters of the same type. In this step, the lattice constant of the crystal lattice of the surface of the first electrode 241 is set at almost the same lattice constant of the crystal lattice of the ferroelectric 203, the ferroelectric 203 is epitaxially grown, on the first electrode 241, into a single crystal. Note that the ion-clustered source gas 250 is not made cohesive on any portions other than the openings 242a of the thin film 242 and their vicinity. Therefore, no source gas 250 is thermally decomposed on any portions other than the openings 242a of the thin film 242 and their vicinity. From this, as shown in FIG. 9B, only on the portion of the first electrode 241 exposed in the opening 242a, the ferroelectric 203 is grown into a single crystal. Desirably, during this growth, the crystal of the ferroelectric 203 is grown so that the crystal orientation thereof exhibiting a large polarization is aligned in the perpendicular direction to the upper surface of the first electrode 241.

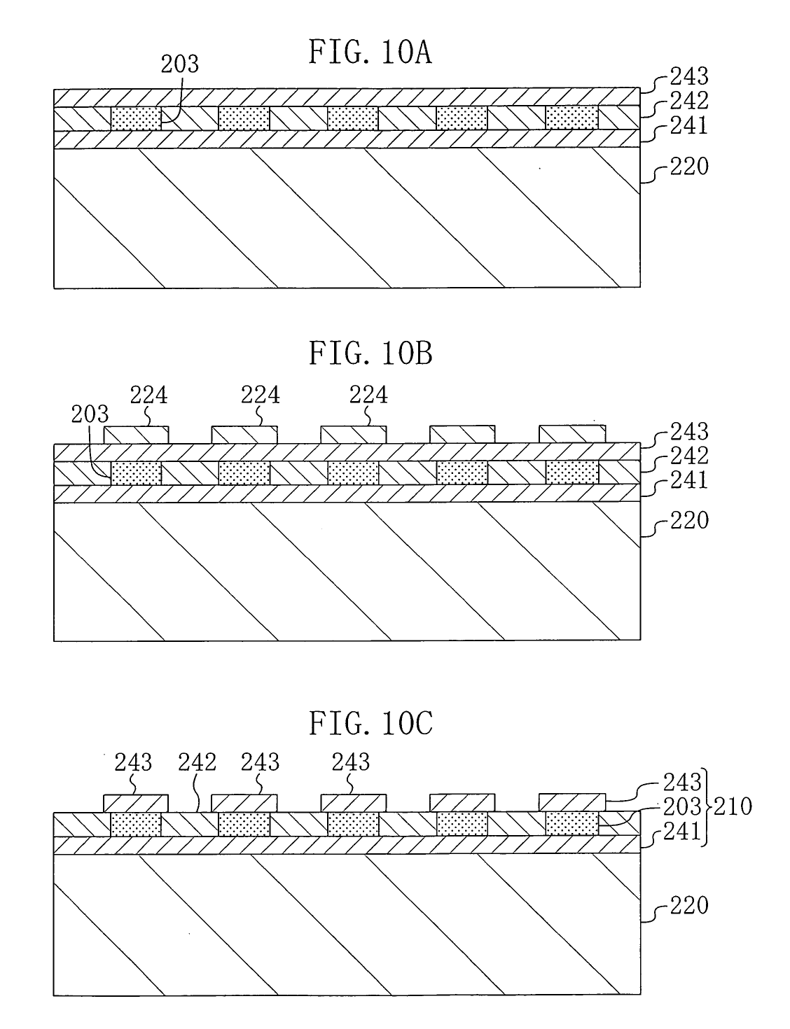

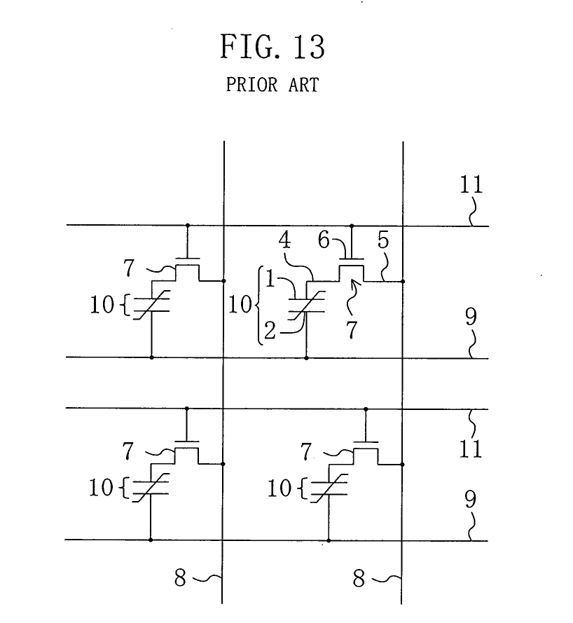

Furthermore, if a film with insulating property, such as a silicon dioxide film, is employed as the thin film 242 like the third embodiment, it can be used as the interlayer insulating film without any procedure. To be more specific, as shown in FIG. 10A, the second electrode 243 made of, for example, platinum (Pt) is formed on the thin film 242 and the ferroelectrics 203. On the formed second electrode 243, a photoresist mask 224 is selectively formed to cover the upper portion of the capacitor film formed of the ferroelectric 203. Subsequently, the second electrode 243 is patterned using the photoresist mask 224, and then the photoresist mask 224 is removed to obtain a plurality of ferroelectric capacitors 210, as shown in FIG. 10C, each of which is composed of the first electrode 241, the ferroelectric 203, and the second electrode 243. Thereafter, the first electrodes 241 and the second electrodes 243 are connected to the peripheral circuit to form the semiconductor memory device having circuitry as shown in, for example, FIG. 13.

As described above, in the third embodiment, the ferroelectric 203 as the capacitor film forming the ferroelectric capacitor 210 is made of a single crystal, and an electric field is applied along the crystal orientation thereof and in the direction in which a relatively large polarization arises in the ferroelectric 203.

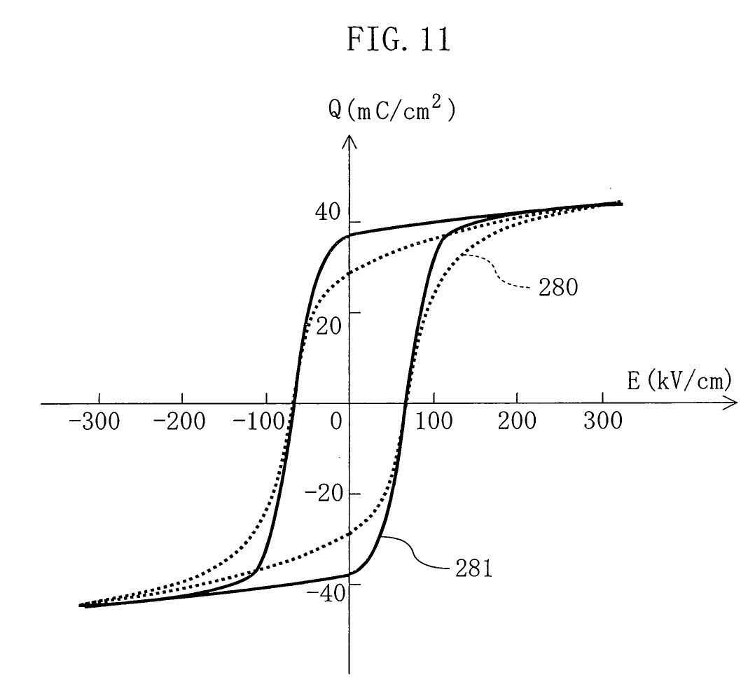

Moreover, the ferroelectrics 203 included in the ferroelectric capacitors 210 are selectively formed on the portions of the first electrode 241 exposed in the openings 242a formed in the thin film 242. Thus, patterning of the capacitor film is unnecessary, and creation of damage regions by etching or the like is eliminated. This enables the occurrence of a large polarization the ferroelectric material originally has. Owing to this, as shown in FIG. 11, the polarization hysteresis characteristics 281 of the ferroelectric capacitor 210 according to the third embodiment have an outstanding electric field response as compared to the polarization hysteresis characteristics 280 of the conventional ferroelectric capacitor made of polycrystal. This significantly improves the data writing and reading characteristics of the memory cell. Note that FIG. 11 plots the strength of the electric field in abscissa and the charge amount per unit area in ordinate.

The ferroelectric 203 may be formed of a domain which has a uniformly aligned crystal orientation or a sole domain.

### Modification of Third Embodiment

A modification of the third embodiment of the present invention will be described below with reference to the accompanying drawings.

This modification is another example of the selective growth method of a capacitor film shown in FIG. 8C according to the third embodiment. This modification employs a liquid phase epitaxy method (electrophoresis method) for the step of selectively forming the ferroelectric 203 in the multiple openings 242a provided in the thin film 242 on the semiconductor substrate 220 or in the openings 242a and on their vicinities.

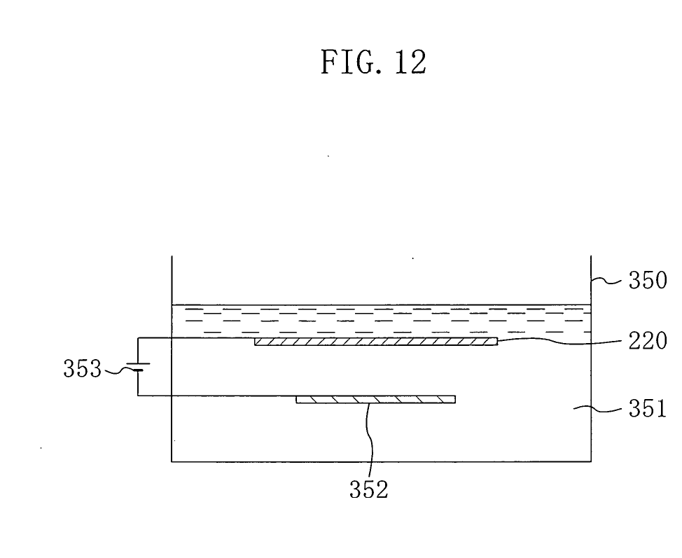

Referring to FIG. 12, first, a liquid treatment bath 350 is filled with a liquid 351 containing a number of particles made of ferroelectric. The liquid 351 has an acidity adjusted to monodisperse the ferroelectric particles. Desirably, ferroelectric particles dispersed in the liquid 351 have previously been sintered, before they are dispersed into the liquid 351, to the crystal phase in which they exhibit ferroelectricity. With this process, the ferroelectric particles monodispersed in the liquid 351 have dielectric constants exhibiting a large anisotropy because the particles are single crystals. The diameter of the particle made of ferroelectric is preferably about 5 to 500 nm.

Next, the semiconductor substrate 220 in the state shown in FIG. 8B and a treatment bath electrode 352 are immersed in the liquid 351 with the substrate and the electrode facing each other. The anode of a direct current source 353 is connected to the first electrode 241 of the semiconductor substrate 220 and the cathode thereof is connected to the treatment bath electrode 352, whereby a strong electric field is applied between the first electrode 241 and the treatment bath electrode 352. This strong electric field generates an interaction between the portion of the first electrode 241 exposed in each opening 242a and a dipole moment of the ferroelectric particle monodispersed in the liquid 351, whereby the ferroelectric particle is selectively attracted to the exposed portion of the first electrode 241. Moreover, the dipole moments of the ferroelectric particles are maximized in the crystal axis direction in which spontaneous polarization arises in the particles, so that the ferroelectric particles fill the openings 242a of the thin film 242 while they are selectively coordinated so that the direction in which their spontaneous polarizations are maximized is naturally perpendicular to the exposed surface of the first electrode 241.

Subsequently to this, like the third embodiment, the process steps shown in FIGS. 10A, 10B and 10C are performed to obtain a plurality of ferroelectric capacitors 210 each of which is composed of the first electrode 241, the ferroelectric 203 and the second electrode 243. Thereafter, the first electrodes 241 and the second electrodes 243 are connected to the peripheral circuit to form the semiconductor memory device including circuitry as shown in, for example, FIG. 13.

In the ferroelectric capacitor 210 provided in this modification, the ferroelectric 203 as a capacitor film constituting the ferroelectric capacitor 210 is made of a single crystal or an assembly of single crystal particles with aligned crystal orientations, and an electric field is applied along the crystal orientation exhibiting a large polarization. Therefore, as shown in FIG. 11, the polarization hysteresis characteristics 281 of the ferroelectric capacitor 210 according to this modification also have an outstanding response as compared to the polarization hysteresis characteristics 280 of the conventional ferroelectric capacitor made of polycrystal.

Moreover, if the shapes of the ferroelectric particles monodispersed in the liquid 351 are made uniform, the processing step for the ferroelectric capacitor 210 becomes unnecessary. This eliminates creation of damage regions in the capacitor film formed of the ferroelectric 203, thereby enabling the occurrence of a large polarization. Thus, the data writing and reading characteristics of the memory cell are significantly improved.

In the liquid phase epitaxy step shown in FIG. 12, if mechanical vibration such as ultrasonic wave is applied to the semiconductor substrate 220, translational kinetic energy of the ferroelectric particle on the substrate surface increases. This further enhances the selective growth capability. Also, in the above step, the ferroelectric particle is radiated with an energy beam such as a light beam or an electron beam to raise translational kinetic energy of the ferroelectric particle on the substrate surface, whereby the selective growth capability can be further enhanced.

Moreover, in the liquid phase epitaxy step, if the standard deviation representing the extend to which the particle diameters of the particles made of ferroelectric vary is equal to or smaller than the average of the particle diameters, the selectivity of arrangement of the ferroelectric particles and the homogeneity of electric characteristics of the ferroelectric capacitors 210 can be significantly improved.

In the third embodiment and its modification, ferroelectric is used for the capacitor film of the ferroelectric capacitor. However, the capacitor film is not limited to the ferroelectric, and a dielectric with high dielectric constant, such as barium strontium titanate ((Sr, Ba)TiO₃) or tantalum pentoxide (Ta₂O₅), can be used instead.

The semiconductor memory device and the fabrication method thereof according to the present invention can prevent creation of a damage region in the capacitor film of ferroelectric or high dielectric constant material, and can control the crystal orientation of the ferroelectric in the direction in which the deviation of polarization thereof is maximized. Therefore, the inventive semiconductor memory device and its fabrication method are of usefulness in a semiconductor memory device capable of improving the data writing and reading characteristics of the memory cell therein and in a fabrication method of such a device.

1. A semiconductor memory device comprising a plurality of memory cells,
wherein the memory cells each include a capacitor which is composed of a first electrode, at least one particle made of ferroelectric or high dielectric constant material and selectively arranged on the first electrode, and a second electrode formed on the particle.

2. The device of claim 1,
wherein the first electrodes of the memory cells are regularly arranged on a semiconductor substrate.

3. The device of claim 2, further comprising an insulating film formed on the first electrodes,
wherein the insulating film includes a plurality of openings reaching the first electrodes, respectively, and the particles enter in the openings so that a part of the particle of each said memory cell is in contact with the first electrode.

4. The device of claim 1,
wherein the particles are sintered in advance into a crystal phase to exhibit ferroelectricity.

5. The device of claim 4,
wherein each said particle is a single crystal or a crystal of mono-domain.

6. The device of claim 1,
wherein the standard deviation representing the variation in the particle diameter is equal to or smaller than the average value of the particle diameters.

7. The device of claim 1,
wherein the capacitors are connected to respective select switches to form a memory cell array.

8. The device of claim 7,
wherein the select switch is formed of a transistor, a bidirectional diode or a unidirectinal diode.

9. The device of claim 1, comprising:
a first memory cell array in which the multiple memory cells are arranged; and
a second memory cell array formed on the first memory cell array and having the same structure as the first memory cell array.

10. A method for fabricating a semiconductor memory device, comprising the steps of:
(a) selectively forming a plurality of first electrodes on a semiconductor substrate;
(b) dispersing in a liquid a plurality of particles made of ferroelectric or high dielectric constant material;
(c) selectively arranging the particles on the plurality of first electrodes, respectively, while the semiconductor substrate with the first electrodes formed thereon is immersed in the liquid; and
(d) forming a second electrode on the particles to form a plurality of capacitors each of which is composed of one of the first electrodes, at least one of the particles, and the second electrode.

11. The method of claim 10,
wherein in the step (b), the particles are monodispersed in a liquid.

12. The method of claim 10,
wherein before the step (b), the particles are sintered into a crystal phase to exhibit ferroelectricity.

13. The method of claim 12,
wherein each said particle is a single crystal or a crystal of mono-domain.

14. The method of claim 10,
wherein in the step (c), an electric field is applied to the particles.

15. The method of claim 10,
wherein in the step (c), mechanical vibration is applied to the particles or the semiconductor substrate.

16. The method of claim 10,
wherein in the step (c), the particles are radiated with energy beams.

17. The method of claim 10, further comprising, between the steps (c) and (d),
the step (e) of forming an insulating film on the semiconductor substrate so that the particles are covered with the insulating film, and
the step (f) of removing an upper portion of the insulating film until a part of the particles are exposed.

18. A method for fabricating a semiconductor memory device, comprising the step of:
(a) forming a first electrode on a semiconductor substrate;
(b) forming a thin film on the first electrode;
(c) forming in the thin film an opening reaching the first electrode;
(d) selectively forming a capacitor insulating film of ferroelectric or high dielectric constant material in the opening formed in the thin film or in the opening and on its vicinity; and
(e) forming a second electrode on the capacitor insulating film to form a capacitor composed of the first electrode, the capacitor insulating film and the second electrode.

19. The method of claim 18,
wherein in the step (d), the capacitor insulating film is formed by a metal organic chemical vapor deposition method in which a source gas for the ferroelectric or high dielectric constant mateiral is formed into ion clusters.

20. The method of claim 18,
wherein in the step (d), the capacitor insulating film is formed by an electrophoresis method using ferroelectrics or high dielectric constant materials monodispersed in a liquid.

21. The method of claim 20,
wherein in the step (d), mechanical vibration is applied to the semiconductor substrate.

22. The method of claim 20,
wherein in the step (d), the monodispersed ferroelectrics or high dielectric constant materials are radiated with energy beams.

23. The method of claim 18,
wherein in the step (c), the opening is formed by radiating energy beams directly on a portion of the thin film to alter the portion and removing the altered portion.

24. The method of claim 18,
wherein the thin film is an insulating film.
